(19) United States
(12) Patent Application Publication
(10) Pub. No.: US 2018/0006653 A1
(43) Pub. Date: Jan. 4, 2018

(54) INTEGRATED CIRCUITS WITH HYBRID FIXED/CONFIGURABLE CLOCK NETWORKS

(71) Applicant: Altera Corporation, San Jose, CA (US)

(72) Inventors: Kenneth Duong, San Jose, CA (US); Jung Ko, Santa Clara, CA (US)

(21) Appl. No.: 15/197,403

(22) Filed: Jun. 29, 2016

(51) Int. Cl. H03K 19/177; H03K 19/173; G06F 1/10; G06F 1/08

(52) U.S. Cl. CPC H03K 19/1774; H03K 19/1776; H03K 19/17744; G06F 1/08; H03K 19/1735; G06F 1/10; H03K 19/1737

(57) ABSTRACT

An integrated circuit with a clock distribution network is provided. The clock distribution network may include configurable clock routing paths linking a clock source to one or more clock tree roots and may also include fixed clock routing paths linking the clock tree roots to corresponding leaf nodes. Both the configurable clock routing paths and the fixed clock routing paths can be implemented using an array of logic regions, where each logic region includes a clock switching box, a horizontal routing segment, a vertical routing segment, and associated logic circuitry. The configurable routing paths may include horizontal/vertical routing segments with bidirectional tristate buffers. The fixed routing paths may include horizontal/vertical routing segments with unidirectional inverters that are configured to form an H-tree.

### BACKGROUND

This relates to integrated circuits and more particularly, to clock routing networks on integrated circuits.

An integrated circuit often contains clock-triggered storage elements such as digital flip-flops. These flip-flops are typically triggered using control signals such as clock signals. The integrated circuit can include a clock source that generates the clock signals for the flip-flops. In general, it is desirable for clock signals to arrive at flip-flops located in different regions of the integrated at the same time. Any unintended deviation between the arrival times of clock signals at the different flip-flops is referred to as clock skew.

In an effort to reduce clock skew, conventional integrated circuits are provided with a fixed clock tree. The fixed clock tree is a non-configurable network of routing paths that serve to route the clock signals from the clock source to the various flip-flops on the integrated circuit with minimal clock skew. This is accomplished by forming each individual clock routing path with substantially equal lengths and path delays. While a fixed clock tree offers reduced clock skew, each newer generation of integrated circuits (e.g., if differing in size) will require a complete redesign of the clock tree.

Moreover, a fixed clock tree cannot easily switch between different clock domains (i.e., a fixed clock tree will only be able to serve a given region within its coverage with a fixed latency). If a larger region of coverage is required, the fixed clock tree cannot be easily extended. If a smaller region of coverage is required, the clock routing latency cannot be easily reduced.

It is within this context that the embodiments described herein arise.

### SUMMARY

An integrated circuit with a hybrid fixed-routed clock network is provided.

In accordance with an embodiment, the hybrid clock network may include a configurable clock routing portion that routes clock signals from a clock source to a clock tree root and a fixed clock routing portion that routes the clock signals from the clock tree root to corresponding clock tree leaf nodes (e.g., to registers, counters, etc.). Arranged in this way, the configurable clock routing portion provides a common path for the clock signals, whereas the fixed clock routing portion provides divergent paths branching off from the clock tree root.

The configurable and fixed clock routing portions may be implemented using an array of logic regions (sometimes referred to as “sectors”). Each logic region may include a clock switching block, a horizontal routing segment, a vertical routing segment, and associated programmable logic circuitry. The clock switching block may include four 4:1 multiplexers that receive the same clock signals.

The horizontal/vertical routing segments that are used to implement the configurable routing portion may include bidirectional tristate buffers. On the other hand, horizontal/vertical routing segments that are used to implement the fixed routing portion may include simple inverters that exhibit less latency than the tristate buffers. The fixed clock routing portion may also be arranged in an H-tree mesh. A hybrid clock network formed in this way can be used to provide coverage for any suitable region on an integrated circuit.

Further features of the invention, its nature and various advantages will be more apparent from the accompanying drawings and following detailed description.

### BRIEF DESCRIPTION OF THE DRAWINGS

FIG. 1 is a diagram of an illustrative programmable integrated circuit in accordance with an embodiment.

FIG. 2 is a diagram of an illustrative clock distribution network on an integrated circuit in accordance with an embodiment.

FIG. 3 is a diagram of an illustrative hybrid clock distribution network that includes configurable clock routing circuitry and fixed clock routing circuitry in accordance with an embodiment.

FIG. 4 is a diagram of an illustrative array of programmable logic regions in accordance with an embodiment.

FIG. 5 is a diagram of an illustrative clock switching block in accordance with an embodiment.

FIG. 6A is a diagram of an illustrative configurable bidirectional buffer in accordance with an embodiment.

FIG. 6B is a circuit diagram of an illustrative tristate buffer in accordance with an embodiment.

FIG. 7A is a diagram of an illustrative fixed inverter configured to drive signals in a first direction in accordance with an embodiment.

FIG. 7B is a diagram of an illustrative fixed inverter configured to drive signals in a second direction that is different than the first direction of FIG. 7A in accordance with an embodiment.

FIG. 7C is a circuit diagram of an illustrative fixed inverter in accordance with an embodiment.

FIG. 8 is a diagram showing a configurable clock routing network implemented using an array of programmable logic regions in accordance with an embodiment.

FIG. 9 is a diagram showing a fixed global clock routing network implemented using the array of programmable logic regions shown in FIG. 8 in accordance with an embodiment.

FIG. 10 is a diagram showing how regional clock distribution networks can be implemented using only configurable clock routing circuitry in accordance with an embodiment.

### DETAILED DESCRIPTION

Embodiments of the present invention relate to integrated circuits and in particular, to programmable integrated circuits with clock distribution networks.

A programmable integrated circuit may include an array of programmable logic regions (sometimes referred to as logic “sectors”). Each of the programmable sectors in the array may include circuitry for implementing configurable clock routing paths and/or fixed clock routing paths. To implement a global clock routing network, a first portion of the global clock routing network may include configurable clock routing paths, whereas a second portion of the global clock routing network may include fixed clock routing paths. To implement a regional, peripheral, or other smaller clock domains on the integrated circuit, only configurable clock routing paths might be used. Arranged in this way, the configurable portion of the clock routing network provides flexibility and composability while the fixed portion of the clock routing network provides reduced latency and increased tolerance to uneven transistor aging/variability.

It will be recognized by one skilled in the art that the present exemplary embodiments may be practiced without some or all of these specific details. In other instances, well-known operations have not been described in detail in order not to unnecessarily obscure the present embodiments.

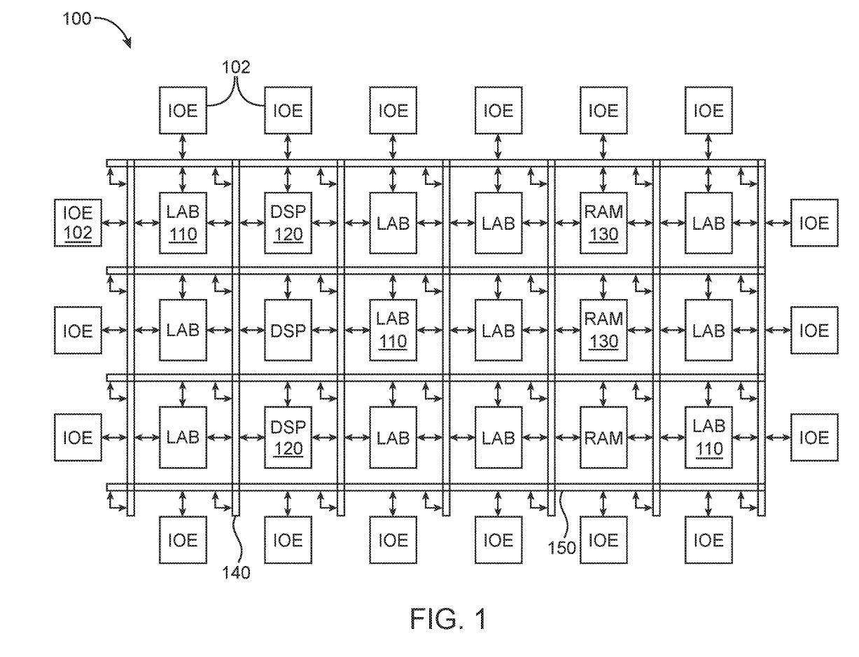

An illustrative integrated circuit such as a programmable logic device (PLD) 100 is shown in FIG. 1. As shown in FIG. 1, programmable integrated circuit 10 may include a two-dimensional array of functional blocks, including logic array blocks (LABs) 110 and other functional blocks, such as random access memory (RAM) blocks 130 and digital signal processing (DSP) blocks 120, for example. Functional blocks such as LABs 110 may include smaller programmable regions (e.g., logic elements, configurable logic blocks, or adaptive logic modules) that receive input signals and perform custom functions on the input signals to produce output signals.

Programmable device 100 may contain programmable memory elements. Memory elements may be loaded with configuration data (also called programming data) using input/output elements (IOEs) 102. Once loaded, the memory elements each provide a corresponding static control signal that controls the operation of an associated functional block (e.g., LABs 110, DSP 120, RAM 130, or input/output elements 102).

In a typical scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration RAM (CRAM), or programmable memory elements. The CRAM cells may be different than RAM blocks 130 in the sense that CRAM cells store configuration data that remains relatively constant while RAM blocks 130 store user data that can change often during normal operation of device 100.

In addition, the programmable logic device may have input/output elements (IOEs) 102 for driving signals off of PLD and for receiving signals from other devices. Input/output elements 102 may include parallel input/output circuitry, serial data transceiver circuitry, differential receiver and transmitter circuitry, or other circuitry used to connect one integrated circuit to another integrated circuit. As shown, input/output elements 102 may be located around the periphery of the chip. If desired, the programmable logic device may have input/output elements 102 arranged in different ways. For example, input/output elements 102 may form one or more columns of input/output elements that may be located anywhere on the programmable logic device (e.g., distributed evenly across the width of the PLD). If desired, input/output elements 102 may form one or more rows of input/output elements (e.g., distributed across the height of the PLD). Alternatively, input/output elements 102 may form islands of input/output elements that may be distributed over the surface of the PLD or clustered in selected areas.

The PLD may also include programmable interconnect circuitry in the form of vertical routing channels 140 (i.e., interconnects formed along a vertical axis of PLD 100) and horizontal routing channels 150 (i.e., interconnects formed along a horizontal axis of PLD 100), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 1, are intended to be included within the scope of the present invention. For example, the routing topology may include wires that travel diagonally or that travel horizontally and vertically along different parts of their extent as well as wires that are perpendicular to the device plane in the case of three dimensional integrated circuits, and the driver of a wire may be located at a different point than one end of a wire. The routing topology may include global wires that span substantially all of PLD 100, fractional global wires such as wires that span part of PLD 100, staggered wires of a particular length, smaller local wires, or any other suitable interconnection resource arrangement.

Furthermore, it should be understood that embodiments may be implemented in any integrated circuit. If desired, the functional blocks of such an integrated circuit may be arranged in more levels or layers in which multiple functional blocks are interconnected to form still larger blocks. Other device arrangements may use functional blocks that are not arranged in rows and columns.

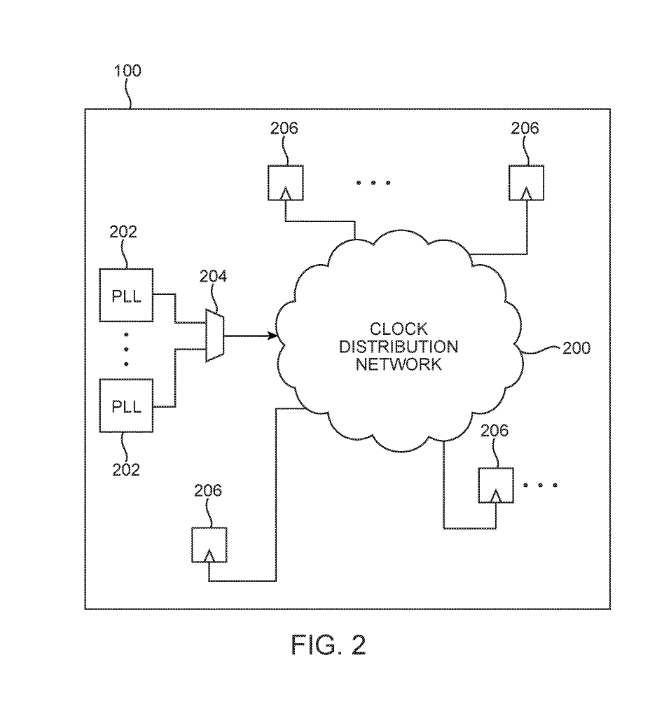

In accordance with an embodiment, programmable integrated circuit 100 may include a clock distribution network such as clock distribution network 200 that routes clock signals to various portions of IC die 100 (see FIG. 2). As shown in FIG. 2, device 100 may include one or more clock sources such as phase-locked loop (PLL) circuits 202 for generating clock signals. Device 100 may also include a switching circuit such as multiplexer 204 for selectively passing through one of the clock signals generated by PLLs 202 to clock distribution network 200.

Clock distribution network 200 may include routing paths for routing the select clock signal(s) to different locations on integrated circuit 100. For example, integrated circuit 100 may include clocked storage elements such as registers 206 formed at different physical locations on integrated circuit 100. Registers 206 may be controlled using the clock signals routed through clock distribution network 200. In order to ensure that all clock signals arrive at the different registers 206 at roughly the same time, clock distribution network 200 may be configured in a mesh-like structure to minimize clock skew between the different clock routing paths.

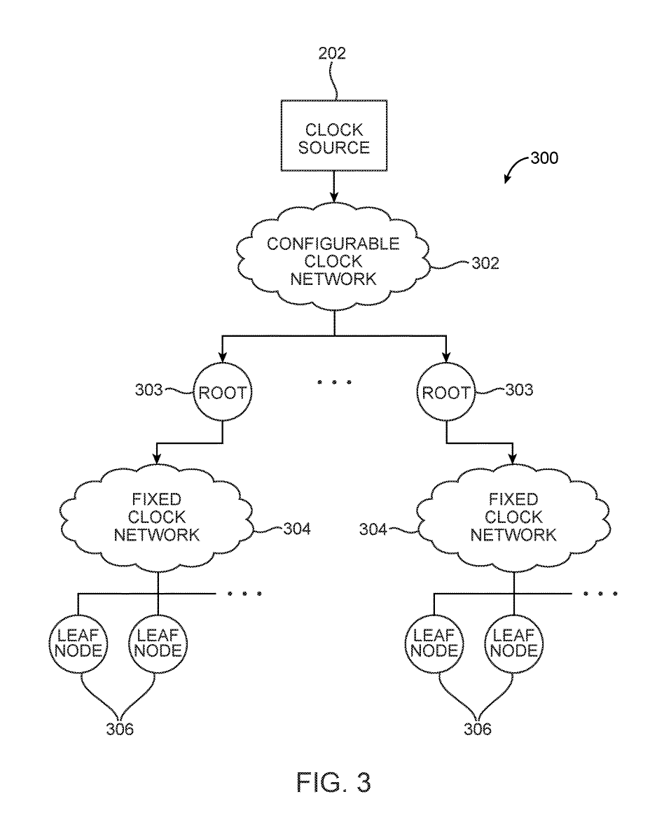

FIG. 3 shows one suitable arrangement of a clock distribution network that includes both configurable routing paths and fixed routing paths. As shown in FIG. 3, overall clock network 300 may include configurable clock network 302 that receives clock signals from clock source 202 (e.g., from one of PLLs 202 in FIG. 2) and may also include one or more fixed clock networks 304. Configurable clock network 302 can be easily reconfigured to route through different portions of device 100, whereas fixed clock network 302 has a structure that cannot be readily altered. Overall clock network 302 that includes both configurable clock network 302 (sometimes referred to as “routed” or “re-routable” clock distribution circuitry) and fixed clock network 304 (sometimes referred to as hardwired clock routing circuitry) can therefore sometimes be referred to as a hybrid clock distribution network.

Clock distribution network 300 can sometimes be referred to as a clock “tree.” A clock tree may include common paths and divergent paths. Common paths represent all routing paths linking the clock source to a clock tree “root” (e.g., all clock signals traveling through network 300 needs to traverse through the common paths regardless of its final destination). Divergent paths represent all routing paths branching off separately from a clock tree root, linking the root to a corresponding clock tree “leaf” node 306. Each leaf node 306 may be a register, counter, or other circuits that can be controlled by a clock signal. Since configurable clock routing circuitry 302 is more susceptible to random clock tree skew induced by uneven transistor aging, it may be desirable to implement the common paths linking clock source 202 to root(s) 303 using configurable clock network 302. From the clock root(s) on, the clock tree may be stripped of all is configurable elements to improve divergent path latency to form fixed clock network(s) 304.

Because the fixed portion of the hybrid clock tree begins at the first divergent point of the tree (i.e., at a root 303), the impact of transistor variability is mitigated. Additionally, the transistors in all fixed branches 304 will age equally and thus will not introduce skew. The use of fixed clock network 304 can also help reduce power supply jitter from the overall clock insertion delay, which is roughly quartered in register setup cases and halved in register hold cases.

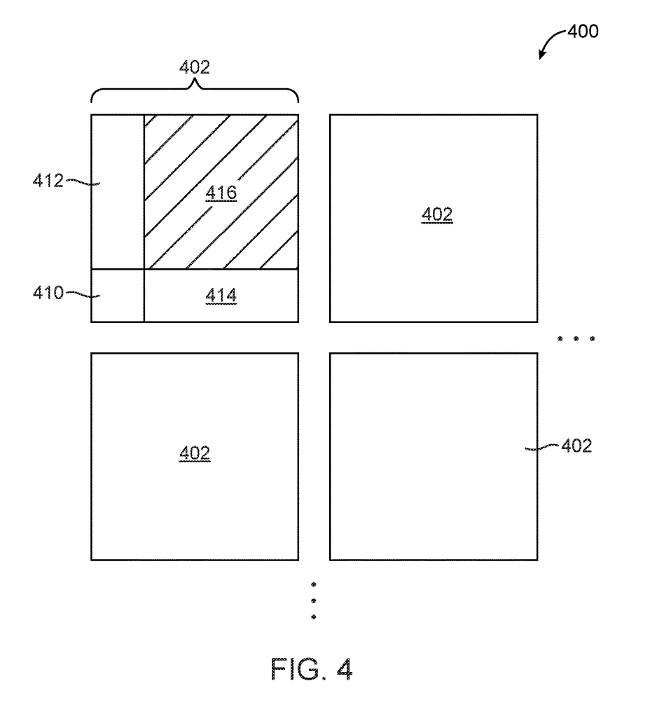

Clock routing network 300 of FIG. 3 may be implemented using an array of logic regions such as logic regions 402 (FIG. 4). As shown in FIG. 4, each logic region 402 (sometimes referred to as a logic “sector”) may include a clock switching block such as block 410, a vertical clock routing segment 412, a horizontal clock routing segment 414, and associated logic circuits 416 (see, e.g., shaded region in FIG. 4). Logic circuits 416 in each region 402 may (as an example) include an array of LABs 110. This is merely illustrative. Logic circuits 416 in each region 402 may include any suitable amount of programmable logic components. Using a sector-based architecture to implement at least a partially routable clock network provides superior chip composability (e.g., larger clock trees can be supported by merely adding more sectors 402) and flexibility to shape the clock tree depth for different clock domains.

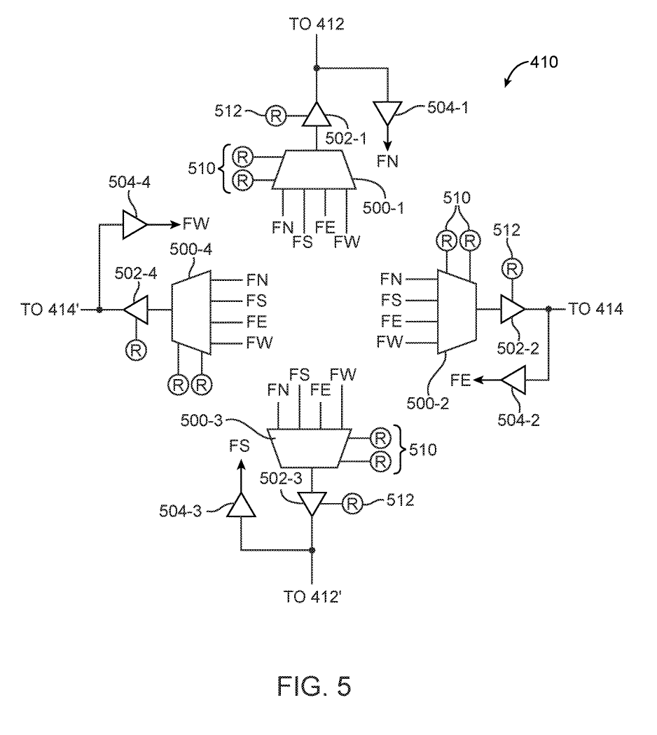

Clock switching block 410 may serve to route clock signals between adjoining vertical routing segments 412 and horizontal routing segments 414 between adjacent logic regions 402. FIG. 5 is a circuit diagram of illustrative clock switching block 410 in accordance with an embodiment. As shown in FIG. 5, block 410 may include a first 4:1 multiplexer 500-1 that has an output driven by buffer 502-1. The output of buffer 502-1 may be fed to vertical routing segment 412 in the same clock switching block and may also be fed back as a “from North” signal FN via buffer 504-1. Block 410 may also include a second 4:1 multiplexer 500-2 that has an output driven by buffer 502-2. The output of buffer 502-2 may be fed to horizontal routing segment 412 in the same clock switching block and may also be fed back as a “from East” signal FE via buffer 504-2. Block 410 may also include a third 4:1 multiplexer 500-3 that has an output driven by buffer 502-3. The output of buffer 502-3 may be fed to vertical routing segment 412′ in an adjacent clock switching block below and may also be fed back as a “from South” signal FS via buffer 504-3. Block 410 may also include a fourth 4:1 multiplexer 500-4 that has an output driven by buffer 502-4. The output of buffer 502-4 may be fed to horizontal routing segment 414′ in yet another adjacent clock switching block to the right and may also be fed back as a “from West” signal FW via buffer 504-4.

Each multiplexer 500 (e.g., multiplexers 500-1, 500-2, 500-3, and 500-4) may receive signals FN, FS, FE, and FW and may be configured using static control bits stored on memory elements 510. Depending on the bits currently stored in memory elements 510, multiplexer 500 may route signals from a selected one of its four inputs to its output. Output drivers 502 (e.g., buffers 502-1, 502-2, 502-3, and 502-4) may be tristate buffers that are controlled using static control bits stored on memory elements 512. For example, if the control bit in memory element 512 is asserted, corresponding driver 502 may be activated. If, however, the control bit in memory element 512 is deasserted, the corresponding driver 502 may be switched out of use (i.e., temporarily disabled). Memory elements 510 and 512 may (for example) be volatile RAM elements or non-volatile storage elements.

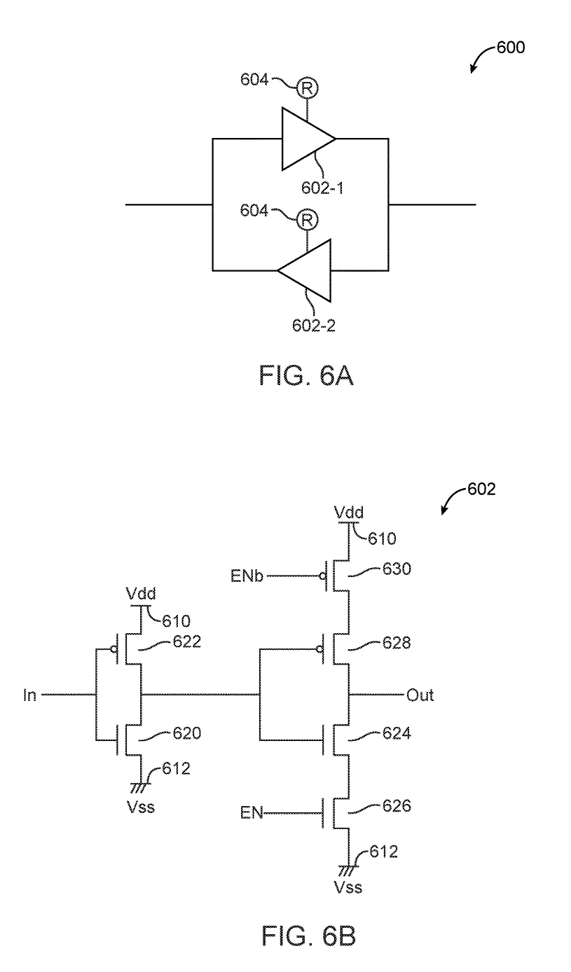

FIG. 6A is a diagram of an illustrative configurable bidirectional routing segment 600 that can either serve as horizontal clock routing segment 414 or vertical clock routing segment 412 of FIG. 4 in a configurable/routed clock network. As shown in FIG. 6A, routing segment 600 may include a first tristate buffer 602-1 that drives signals in a first direction and a second tristate buffer 602-2 that drives signals in a second direction that opposes the first direction. Buffers 602-1 and 602-2 may be enabled using control bits stored on memory elements 604. At most one of the two buffers 602 can be activated at any point in time.

FIG. 6B is a circuit diagram of an illustrative tristate buffer 602 in accordance with an embodiment. As shown in FIG. 6A, buffer 602 may include a first inverter stage connected in series with a second tristatable inverting stage. The first inverter stage may include re-channel transistor 620 coupled in series with p-channel transistor 622 between positive power supply line 610 (e.g., a first power supply line on which positive power supply voltage Vdd is provided) and ground power supply line 612 (e.g., a second power supply line on which ground voltage Vss is provided). Second inverting stage may include re-channel transistors 624 and 626 and p-channel transistors 628 and 630 coupled in series between power supply lines 610 and 612. Transistors 624 and 628 may have gate terminals that are connected to the output of the first inverter stage. Transistor 626 has a gate that receives enable signal EN, whereas transistor 630 has a gate that receives an inverted version of the enable signal (ENb). Buffer 602 may be placed in an active mode whenever signal EN is high or may be placed in a tristate/inactive mode when signal EN is low.

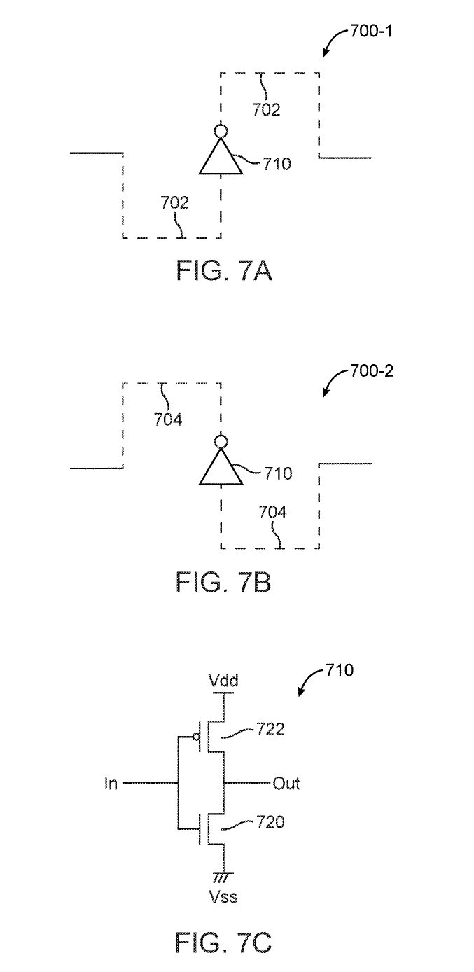

While FIG. 6A shows routing segment 600 that is part of a configurable/routed clock network, FIGS. 7A and 7B show fixed routing segments that are part of a fixed clock network. FIG. 7A shows a fixed routing segment 700-1 that includes simple inverter 710 that is wired using metal options 702 to route signals in only a first direction (from left to right in the orientation of FIG. 7A). FIG. 7B shows a fixed routing segment 700-2 that includes a simple inverter 710 that is wired using metal options 704 to route signals in only a second direction (from right to left in the orientation of FIG. 7B). In order to maintain composability, each routing segment 700 would have metal option variants to reverse the direction of any legs or corners of the overall clock tree. Fixed routing segments 700-1 and 700-2 can either serve as horizontal clock routing segment 414 or vertical clock routing segment 412 of FIG. 4 in a fixed clock network.

FIG. 7C is a circuit diagram of a simple inverter such as inverter 710. As shown in FIG. 7C, inverter 710 may include n-channel transistor 720 connected in series with p-channel transistor 722 between the positive power supply terminal and the ground line. Compared to tristate buffer 602 of FIG. 6B, inverter 710 exhibits substantially better performance while consuming less power (since there is only one inverting stage, and inverter 710 includes fewer stacked transistors). As a result, fixed clock routing paths generally exhibit lower clock latency.

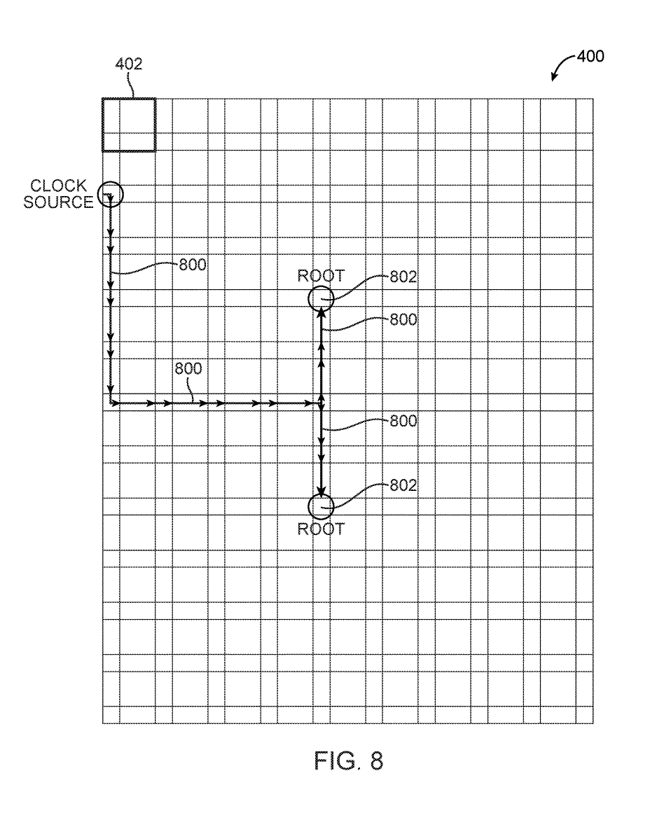

FIG. 8 is a diagram showing a configurable clock routing portion of an overall clock tree implemented using array 400 of logic regions 402 in accordance with an embodiment. As shown in FIG. 8, routing paths 800 serve to route clock signals from a clock source to two different clock tree roots 802. Routing paths 800 may be routed via clock switching block 410 of FIG. 5 and configurable routing segments 600 of FIGS. 6A and 6B within logic sectors 402 through which paths 800 traverse. In other words, routing paths 800 serve as a configurable clock routing network for the common paths linking the clock source to the clock root(s) 802.

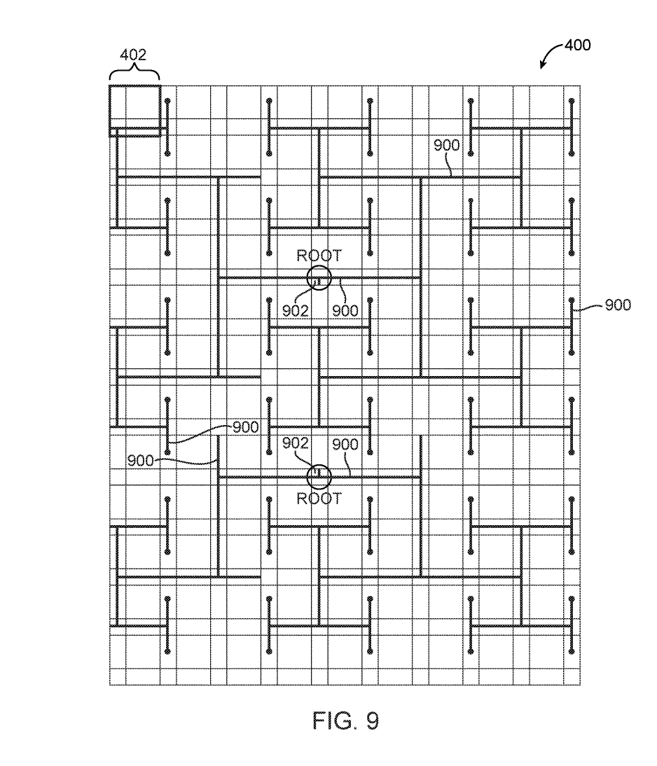

FIG. 9 is a diagram showing a fixed clock routing portion of the overall clock tree. The diagram of FIG. 9 overlays with the diagram of FIG. 8. Switching block 410 in each logic sector 402 can be expanded to route more than four paths in each direction. Similarly, the horizontal and vertical routing segments in each logic sector 402 can have more than one fixed routing path or more than one configurable routing path in parallel for routing signals in either direction (i.e., north, south, east, or west). As shown in FIG. 9, fixed routing paths 900 are arranged in an H-tree mesh (as an example). Arranged in this way, fixed routing paths 900 serve as a fixed clock routing network for the divergent paths linking the clock tree root(s) 902 to the individual leaf nodes.

The example of FIGS. 8 and 9 shows merely one way how a relatively large “global” clock tree can be implemented using both the configurable clock routing network (for the common paths) and the fixed clock routing network (for the divergent paths). This same concept can also be applied to medium and smaller clock regions as well, albeit with more moderate gains. For example, fixed low-latency clock trees can be placed across the integrated circuit in the most common clock region sizes, again leveraging the configurable/routed clock plane to route to the root of each region to minimize the distance from the clock source.

The premise is the same whether implement large or small clock trees; lower latency routing segments (e.g., the fixed routing segments shown in FIGS. 7A and 7B) perform better than higher latency routing segments (e.g., the configurable routing segments shown in FIG. 6A), and lower depth clock trees perform better than higher depth clock trees. The hybrid clock distribution network would take advantage of both the lower latency offered by the fixed clock network and the lower depth offered by the configurable clock network.

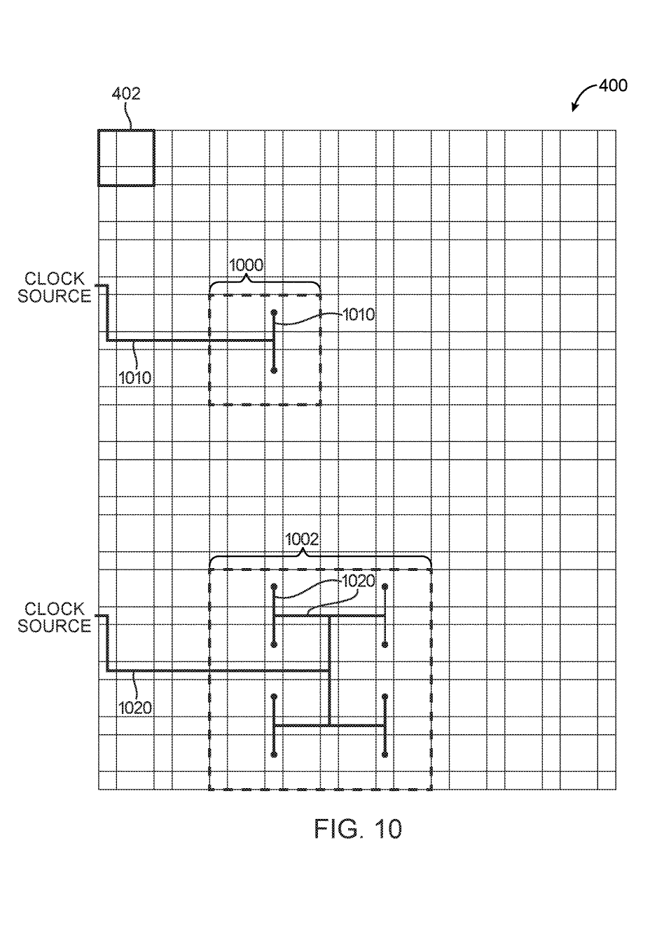

FIG. 10 shows an example of smaller clock regions that can be implemented using array 400 of logic sectors 402. As shown in FIG. 10, clock region 1000 may be supported using only configurable clock routing paths 1010 that route signals directly from a first clock source. On the other hand, clock region 1002 may be supported using only configurable clock routing paths 1020 that route signals directly from a second clock source. If desired, the mini clock tree within region 1002 may be implemented using either configurable routing segments or fixed routing segments. In general, the concepts described herein can be extended to support clock domains of any size within an integrated circuit.

The embodiments thus far have been described with respect to integrated circuits. The methods and apparatuses described herein may be incorporated into any suitable circuit. For example, they may be incorporated into numerous types of devices such as programmable logic devices, application specific standard products (ASSPs), and application specific integrated circuits (ASICs). Examples of programmable logic devices include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The programmable logic device described in one or more embodiments herein may be part of a data processing system that includes one or more of the following components: a processor; memory; IO circuitry; and peripheral devices. The data processing can be used in a wide variety of applications, such as computer networking, data networking, instrumentation, video processing, digital signal processing, or any suitable other application where the advantage of using programmable or re-programmable logic is desirable. The programmable logic device can be used to perform a variety of different logic functions. For example, the programmable logic device can be configured as a processor or controller that works in cooperation with a system processor. The programmable logic device may also be used as an arbiter for arbitrating access to a shared resource in the data processing system. In yet another example, the programmable logic device can be configured as an interface between a processor and one of the other components in the system. In one embodiment, the programmable logic device may be one of the family of devices owned by ALTERA/INTEL Corporation.

The foregoing is merely illustrative of the principles of this invention and various modifications can be made by those skilled in the art. The foregoing embodiments may be implemented individually or in any combination.

1. An integrated circuit, comprising:
a clock source that outputs a clock signal;
a clock tree root;
a configurable clock distribution network interposed between the clock source and the clock tree root;
a register; and
a fixed clock distribution network interposed between the clock tree root and the register, wherein the configurable clock distribution network and the fixed clock distribution network are implemented using an array of logic regions.

2. The integrated circuit of claim 1, wherein the configurable clock distribution network provides a common path for the clock signal.

3. The integrated circuit of claim 1, wherein the fixed clock distribution network provides divergent paths branching off from the clock tree root for the clock signal.

4. The integrated circuit of claim 1, wherein the configurable clock distribution network includes a first plurality of routing segments, wherein the fixed clock distribution network includes a second plurality of routing segments, and wherein each of the first plurality of routing segments exhibits greater latency than each of the second plurality of routing segments.

5. (canceled)

6. The integrated circuit of claim 1, wherein each logic region in the array of logic regions comprises:
a clock switching block;
a horizontal routing segment; and
a vertical routing segment.

7. The integrated circuit of claim 6, wherein the clock switching block includes four multiplexers that receive the same clock signals, wherein a first multiplexer in the four multiplexers routes signals to a first adjacent logic region to the north, wherein a second multiplexer in the four multiplexers routes signals to a second adjacent logic region to the east, wherein a third multiplexer in the four multiplexers routes signals to a third adjacent logic region to the south, and wherein a fourth multiplexer in the four multiplexers routes signals to a fourth adjacent logic region to the west.

8. The integrated circuit of claim 6, wherein at least one of the horizontal routing segment and the vertical routing segment includes bidirectional tristate buffers.

9. The integrated circuit of claim 6, wherein at least one of the horizontal routing segment and the vertical routing segment includes unidirectional inverters.

10. The integrated circuit of claim 6, wherein the configurable clock distribution network is implemented using tristate buffers in a first portion of the array of logic regions, and wherein the fixed clock distribution network is implemented using simple inverters in a second portion of the array of logic regions.

11. A method of manufacturing an integrated circuit, comprising:
forming a clock source;
forming configurable clock routing paths that receive clock signals from the clock source, wherein the configurable clock routing paths are routed through a plurality of 4:1 multiplexers coupled in series;
forming fixed clock routing paths that receive the clock signals from the configurable clock routing paths; and
forming a register that receives the clock signals from the fixed clock routing paths.

12. The method of claim 11, wherein forming the clock source comprises forming a phase-locked loop.

13. The method of claim 11, wherein forming the fixed clock routing paths comprises forming a fixed H-tree mesh.

14. The method of claim 11, wherein forming the fixed clock routing paths comprises using metal options to route inverters in only one direction.

15. The method of claim 11, wherein forming the configurable clock routing paths comprises forming bidirectional tristate buffers.

16. Hybrid clock distribution circuitry, comprising:
an input that receives a clock signal;
a configurable clock network that receives the clock signal and that routes the clock signal to a clock tree root; and
a fixed clock network that receives the clock signal from the clock tree root and that routes the clock signal to a clock tree leaf node, wherein the configurable clock network and the fixed clock network are implemented using an array of logic sectors, and wherein each logic sector in the array comprises a plurality of multiplexers configured to receive the same input signals and to route signals to four different adjacent logic sectors in the array.

17. (canceled)

18. The hybrid clock distribution circuitry of claim 16, wherein the logic sectors implementing the configurable clock network include tristate buffers.

19. The hybrid clock distribution circuitry of claim 16, wherein the logic sectors implementing the fixed clock network include simple inverters.

20. The hybrid clock distribution circuitry of claim 16, wherein the fixed clock network comprises an H-tree.

21. The integrated circuit of claim 7, wherein each of the four multiplexers is a 4:1 multiplexer.

22. The integrated circuit of claim 1, wherein the configurable clock distribution network is implemented using a first group of logic sectors in the array in a first configuration, wherein the configurable clock distribution network is implemented using a second group of logic sectors in the array in a second configuration, and wherein the second group of logic sectors is different than the first group of logic sectors.
